(19) United States
(12) Patent Application Publication
(10) Pub. No.: US 2025/0120239 A1
(43) Pub. Date: Apr. 10, 2025

(54) DISPLAY DEVICE

(71) Applicant: LG ELECTRONICS INC., Seoul (KR)

(72) Inventors: Younggil YOO, Seoul (KR); Seungmi BAEK, Seoul (KR)

(73) Assignee: LG ELECTRONICS INC., Seoul (KR)

(21) Appl. No.: 18/836,516

(22) PCT Filed: Feb. 8, 2022
(86) PCT No.: PCT/KR2022/001937

§ 371 Date: Aug. 7, 2024

(51) Int. Cl. H10H 29/85; H10H 29/49

(52) U.S. Cl. CPC H10H 29/8517; H10H 29/49

(57) ABSTRACT

The display device includes at least one semiconductor light emitting device, a first color conversion pattern, a second color conversion pattern, and a light transmitting pattern. At least one semiconductor light emitting device is arranged on each of the first sub-pixel, the second sub-pixel, and the third sub-pixel. The first color conversion pattern is arranged on at least one semiconductor device corresponding to the first sub-pixel and includes first color conversion particles. The second color conversion pattern is arranged on at least one semiconductor device corresponding to the second sub-pixel and includes second color conversion particles. The light transmitting pattern is arranged on at least one semiconductor device corresponding to the third sub-pixel. The area of the first color conversion pattern, the area of the second color conversion pattern, and the area of the light transmitting pattern are different.

### TECHNICAL FIELD

The embodiment relates to a display device.

### BACKGROUND ART

Display devices are being adopted in various fields. In particular, not only TV displays but also AR (Augmented Reality)-based displays and vehicle head-up displays (HUDs) have been receiving much attention recently.

These AR or HUD display devices require ultra-high resolution. To this end, display devices that display images using high-luminance, small-sized light emitting diodes as light sources for pixels are gaining attention.

FIG. 1 is a cross-sectional view illustrating a conventional display device.

Referring to FIG. 1, a light emitting diode 2 emitting light of the same color is disposed in each sub-pixel of the lower substrate 1. A light emitting diode 2 is used as a light source. A color conversion layer 3 and a color filter 5 are arranged in each sub-pixel of the upper substrate 7, and barrier walls 4, 6 are arranged between these sub-pixels. In this case, the lower substrate 1 and the upper substrate 7 are positioned to face each other and then bonded to each other.

In a conventional display device, a light emitting diode 2, a color conversion layer 3, and a color filter 5 are arranged in order in each sub-pixel. After the light of the light emitting diode 2 is color-converted by the color conversion layer 3, light corresponding to a wavelength of a specific band is emitted by the color filter 5.

In a conventional display device, the area of the color conversion layer 3 arranged in each sub-pixel is the same.

The light emitting diode 2 may emit blue light. Since blue light has a higher intensity than green light or red light, the color temperature appears high when white is implemented. In addition, the blue light of the light emitting diode 2 is converted into red light and green light in the color conversion layer 3 corresponding to each sub-pixel. At this time, the light conversion efficiency is different from each other depending on the material properties of the color conversion layer 3 corresponding to each sub-pixel.

Accordingly, since a color temperature difference occurs between each sub-pixel, the gamma correction method was used in the past to overcome this. That is, by adjusting the gamma to lower the peak value of each red or green signal with relatively low brightness by color, the color temperature was adjusted by reducing the emission intensity of the blue light with relatively high brightness.

However, since the conventional gamma correction method does not use the 255 gradations required to express the maximum brightness of each of the red, green, and blue colors that constitute white, a decrease in brightness due to forced gamma adjustment is inevitable. In addition, the conventional gamma correction method has a problem in that a step phenomenon occurs when expressing an image that gradually brightens or gradually darkens when implementing an image.

### DISCLOSURE

### Technical Problem

The embodiment aims to solve the above-mentioned problem and other problems.

Another object of the embodiment is to provide a display device capable of solving a problem due to gamma correction of the display device.

In addition, another object of the embodiment is to provide a display device capable of simplifying an operation circuit by performing color temperature correction at the panel level.

In addition, another object of the embodiment is to provide a display device capable of improving brightness.

The technical objects of the embodiment are not limited to those described in this item, and include those that may be understood through the description of the invention.

### Technical Solution

According to one aspect of the embodiment to achieve the above or other purposes, the display device include a substrate including a first sub-pixel, a second sub-pixel, and a third sub-pixel; at least one semiconductor light emitting device for each of the first sub-pixel, the second sub-pixel, and the third sub-pixel; a first color conversion pattern disposed on the at least one semiconductor device corresponding to the first sub-pixel and including first color conversion particles; a second color conversion pattern disposed on the at least one semiconductor device corresponding to the second sub-pixel and including second color conversion particles; and a light transmitting pattern disposed on the at least one semiconductor device corresponding to the third sub-pixel, and an area of the first color conversion pattern, an area of the second color conversion pattern, and an area of the light transmitting pattern are different.

The semiconductor light emitting devices of each of the first sub-pixel, the second sub-pixel, and the third sub-pixel may generate the same color light.

The semiconductor light emitting device generates a first color light, the first color conversion pattern converts the first color light into a second color light, the second color conversion pattern converts the first color light into a third color light, and the light transmitting pattern may transmit the first color light.

The area of the second color conversion pattern may be larger than the area of the first color conversion pattern.

The area of the first color conversion pattern may be larger than the area of the light transmitting pattern.

The area of the first color conversion pattern is 26±5% of the total area, the area of the second color conversion pattern is 67=5% of the total area, the area of the light transmitting pattern is 7±5% of the total area, and the total area may be the sum of the area of the first color conversion pattern, the area of the second color conversion pattern, and the area of the light transmitting pattern.

The first widths of each of the first color conversion pattern, the second color conversion pattern, and the light transmitting pattern along the first direction may be the same, and the second widths of each of the first color conversion pattern, the second color conversion pattern, and the light transmitting pattern along the second direction may be different.

The second width of the second color conversion pattern may be larger than the second width of the first color conversion pattern.

The second width of the first color conversion pattern may be larger than the second width of the light transmitting pattern.

The display device may include a bank between each of the first color conversion pattern, the second color conversion pattern, and the light transmitting pattern.

The display device may include a first color filter on the first color conversion pattern; a second color filter on the second color conversion pattern; a third color filter on the light transmitting pattern; and a light-shielding pattern between each of the first color filter, the second color filter, and the third color filter.

The area of the second color filter may be larger than the area of the first color filter, and the area of the first color filter may be larger than the area of the third color filter.

The pass wavelength band of the first color filter may be set within the wavelength band range of red light, the pass wavelength band of the second color filter may be set within the wavelength band range of green light, and the pass wavelength band of the third color filter may be set within the wavelength band range of blue light.

The first color filter and the second color filter may be set to transmit light in the yellow wavelength band.

The display device may include first and second assembly wirings for each of the first sub-pixel, the second sub-pixel, and the third sub-pixel; and a barrier wall disposed on the first and second assembly wirings and having at least one assembly hole for each of the first sub-pixel, the second sub-pixel, and the third sub-pixel.

The display device includes an insulating layer on the barrier wall and the at least one semiconductor light emitting device; and an electrode wiring disposed on the insulating layer and connected to one side of the at least one semiconductor light emitting device, and at least one of the first and second assembly wirings may be connected to the other side of the at least one semiconductor light emitting device.

### Advantageous Effects

As shown in FIG. 8 and FIG. 9, at least one semiconductor light emitting device 161 and a first color conversion pattern 341 may be arranged in the first sub-pixel (PX1), at least one semiconductor light emitting device 162 and a second color conversion pattern 342 may be arranged in the second sub-pixel (PX2), and at least one semiconductor light emitting device 163 and a light transmitting pattern 343 may be arranged in the third sub-pixel (PX3).

At least one semiconductor light emitting device 161, 162, 163 arranged in each of the first sub-pixel (PX1), the second sub-pixel (PX2), and the third sub-pixel (PX3) may emit the same color light, for example, blue light. The semiconductor light emitting devices 161, 162, 163 may have a size of micrometers or less.

For example, the first color conversion pattern 341 may convert blue light of at least one semiconductor light emitting device 161 to output red light. For example, the second color conversion pattern 342 may convert blue light of at least one semiconductor light emitting device 162 to output green light. For example, the light transmitting pattern may output blue light of at least one semiconductor light emitting device 163 as it is.

The areas of the first sub-pixel (PX1), the second sub-pixel (PX2), and the third sub-pixel (PX3) may be different.

The areas (A1, A2, A3) of the first color conversion pattern 341, the second color conversion pattern 342, and the light transmitting pattern 343 may be different. For example, the area (A2) of the second color conversion pattern 342 may be larger than the area (A1) of the first color conversion pattern 341, and the area (A1) of the first color conversion pattern 341 may be larger than the area (A3) of the light transmitting pattern 343.

For example, the first widths (W11, W21, W31) of each of the first color conversion pattern 341, the second color conversion pattern 342, and the light transmitting pattern 343 and/or the second widths (W12, W22, W32) of each of the first color conversion pattern 341, the second color conversion pattern 342, and the light transmitting pattern 343 may be different. For example, the second width (W22) of the second color conversion pattern 342 may be larger than the second width (W12) of the first color conversion pattern 341, and the second width (W12) of the first color conversion pattern 341 may be larger than the second width (W32) of the light transmitting pattern 343.

By changing the structure, i.e., the area or width, of the color converter 340 including the first color conversion pattern 341, the second color conversion pattern 342 and the light emitting pattern 343 as described above, not only may the calculation circuit be simplified by eliminating the need for gamma adjustment as in the past, but also the brightness may be significantly improved, thereby enhancing reliability through high image quality.

In addition, by changing the structure of the color converter 340 including the first color conversion pattern 341, the second color conversion pattern 342, and the light transmitting pattern 343, i.e., the area or width, the brightness in white may be improved by more than 5 times compared to the conventional one, thereby significantly improving the image quality.

Meanwhile, the first color filter 361 and the second color filter 362 may be set to transmit light of the same wavelength band. For example, the first color filter 361 and the second color filter 362 may be set to transmit light of the yellow wavelength band. At this time, the third color filter 363 may be omitted. In this case, red light 420 of a lower wavelength band is output by the first color filter 361, green light 430 of a higher wavelength band is output by the second color filter 362, and blue light 410 is directly output from the light projection pattern 343 of the converter 340, so that the color temperature may be lowered and the color purity may be improved.

Further scope of applicability of the embodiments will become apparent from the detailed description below. However, since various changes and modifications within the spirit and scope of the embodiments will become apparent to those skilled in the art, it should be understood that the detailed description and specific embodiments, such as the preferred embodiments, are given by way of example only.

### DESCRIPTION OF DRAWINGS

FIG. 1 is a cross-sectional view illustrating a conventional display device.

FIG. 2 illustrates a living room of a house in which a display device according to an embodiment is arranged.

FIG. 3 is a block diagram schematically illustrating a display device according to an embodiment.

FIG. 4 is a circuit diagram illustrating an example of a pixel of FIG. 3.

FIG. 5 is an enlarged view of a first panel area in the display device of FIG. 2.

FIG. 6 is an enlarged view of an area A2 of FIG. 5.

FIG. 7 is a drawing illustrating an example in which a light emitting device according to an embodiment is assembled to a substrate by a self-assembly method.

FIG. 8 is a plan view schematically illustrating a display device according to an embodiment.

FIG. 9 is a cross-sectional view schematically illustrating a display device according to an embodiment.

FIG. 10 is a cross-sectional view illustrating a display device according to the first embodiment.

FIGS. 11A to 11D are drawings explaining a manufacturing process of a display device according to the first embodiment.

FIG. 12 is a cross-sectional view illustrating a display device according to the second embodiment.

FIGS. 13A to 13C are drawings explaining a manufacturing process of a display device according to the second embodiment.

The sizes, shapes, and values, etc. of the components illustrated in the drawings may differ from the actual ones. In addition, even if the same components are illustrated with different sizes, shapes, and values between the drawings, this is only one example in the drawings, and the same components may have the same sizes, shapes, and values between the drawings.

### MODE FOR INVENTION

Hereinafter, the embodiments disclosed in the present specification will be described in detail with reference to the attached drawings. Regardless of the drawing symbols, identical or similar components will be given the same reference numerals and redundant descriptions thereof will be omitted. The suffixes ‘module’ and ‘part’ used for components in the following description are assigned or used interchangeably in consideration of the ease of writing the specification, and do not have distinct meanings or roles in themselves. In addition, the attached drawings are intended to facilitate easy understanding of the embodiments disclosed in the present specification, and the technical ideas disclosed in the present specification are not limited by the attached drawings. In addition, when an element such as a layer, region, or substrate is mentioned as existing ‘on’ another element, this includes that it may be directly on the other element or that other intermediate elements may exist therebetween.

The display device described in this specification may include a TV, a signage, a mobile phone, a smart phone, a head-up display (HUD) for a car, a backlight unit for a laptop computer, a display for VR or AR, etc. However, the configuration according to the embodiment described in this specification may be applied to a device capable of displaying, even if it is a new product type developed in the future.

The following describes a light emitting device according to an embodiment and a display device including the same.

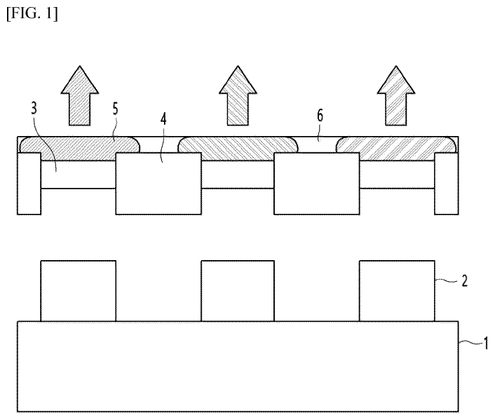

FIG. 1 illustrates a living room of a house in which a display device according to an embodiment is placed.

Referring to FIG. 1, the display device 100 of the embodiment may display the status of various electronic products such as a washing machine 101, a robot vacuum cleaner 102, and an air purifier 103, and may communicate with each electronic product based on IoT, and may also control each electronic product based on user setting data.

The display device 100 according to the embodiment may include a flexible display manufactured on a thin and flexible substrate. The flexible display may be bent or rolled like paper while maintaining the characteristics of a conventional flat panel display.

In a flexible display, visual information may be implemented by independently controlling the light emission of unit pixels arranged in a matrix form. A unit pixel means a minimum unit for implementing one color. A unit pixel of a flexible display may be implemented by a light emitting device. In an embodiment, the light emitting device may be a Micro-LED or a Nano-LED, but is not limited thereto.

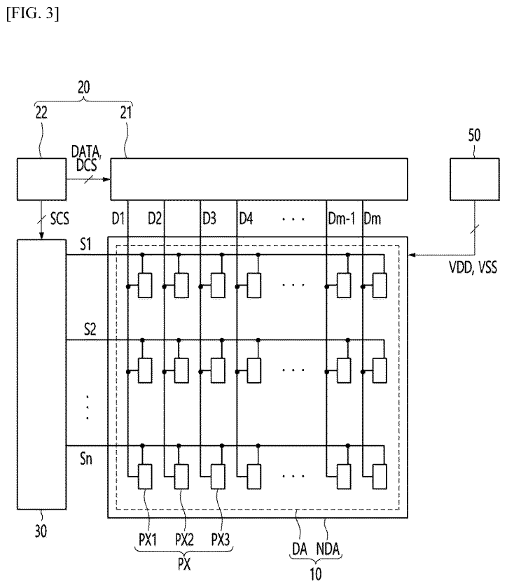

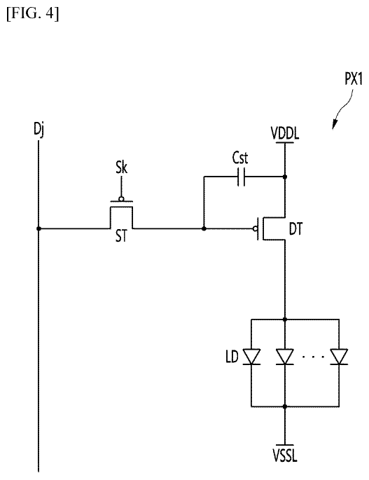

FIG. 3 is a block diagram schematically showing a display device according to an embodiment, and FIG. 4 is a circuit diagram showing an example of a pixel of FIG. 3.

Referring to FIGS. 3 and 4, a display device according to an embodiment may include a display panel 10, a driving circuit 20, a scan driving unit 30, and a power supply circuit 50.

The display device 100 of the embodiment may drive the light emitting device in an active matrix (AM) method or a passive matrix (PM) method.

The driving circuit 20 may include a data driving unit 21 and a timing control unit 22.

The display panel 10 may be formed in a rectangular shape, but is not limited thereto. That is, the display panel 10 may be formed in a circular or oval shape. At least one side of the display panel 10 may be formed to be bent at a predetermined curvature.

The display panel 10 may be divided into a display area (DA) and a non-display area (NDA) arranged around the display area (DA). The display area (DA) is an area where pixels (PX) are formed to display an image. The display panel 10 may include data lines (D1 to Dm, m is an integer greater than or equal to 2, scan lines (S1 to Sn, n is an integer greater than or equal to 2 intersecting the data lines (D1 to Dm), a high-potential voltage line (VDDL) to which a high-potential voltage is supplied, a low-potential voltage line (VSSL) to which a low-potential voltage is supplied, and pixels (PX) connected to the data lines (D1 to Dm) and the scan lines (S1 to Sn).

Each of the pixels (PX) may include a first sub-pixel (PX1), a second sub-pixel (PX2), and a third sub-pixel (PX3). The first sub-pixel (PX1) may emit a first color light of a first main wavelength, the second sub-pixel (PX2) may emit a second color light of a second main wavelength, and the third sub-pixel (PX3) may emit a third color light of a third main wavelength. The first color light may be red light, the second color light may be green light, and the third color light may be blue light, but is not limited thereto. In addition, although FIG. 3 illustrates that each of the pixels (PX) includes three sub-pixels, the present invention is not limited thereto. That is, each of the pixels (PX) may include four or more sub-pixels.

Each of the first sub-pixel (PX1), the second sub-pixel (PX2), and the third sub-pixel (PX3) may be connected to at least one of the data lines (D1 to Dm), at least one of the scan lines (S1 to Sn), and a high-potential voltage line (VDDL). The first sub-pixel (PX1) may include light emitting devices (LD), a plurality of transistors for supplying current to the light emitting devices (LD), and at least one capacitor (Cst), as shown in FIG. 4.

Although not shown in the drawing, each of the first sub-pixel (PX1), the second sub-pixel (PX2), and the third sub-pixel (PX3) may include only one light emitting device (LD) and at least one capacitor (Cst).

Each of the light emitting devices (LD) may be a semiconductor light emitting diode including a first electrode, a plurality of conductivity-type semiconductor layers, and a second electrode. Here, the first electrode may be an anode electrode, and the second electrode may be a cathode electrode, but is not limited thereto.

The light emitting device (LD) may be one of a horizontal light emitting device, a flip-chip light emitting device, and a vertical light emitting device.

The plurality of transistors may include a driving transistor (DT) for supplying current to the light emitting devices (LD), and a scan transistor (ST) for supplying a data voltage to the gate electrode of the driving transistor (DT), as shown in FIG. 4. The driving transistor (DT) may include a gate electrode connected to a source electrode of the scan transistor (ST), a source electrode connected to a high-potential voltage line (VDDL) to which a high-potential voltage is applied, and a drain electrode connected to the first electrodes of the light emitting devices (LD). The scan transistor (ST) may include a gate electrode connected to a scan line (Sk, where k is an integer satisfying 1≤k≤n), a source electrode connected to the gate electrode of the driving transistor (DT), and a drain electrode connected to a data line (Dj, where j is an integer satisfying 1≤j≤m).

The capacitor (Cst) is formed between the gate electrode and the source electrode of the driving transistor (DT). The storage capacitor (Cst) charges the difference between the gate voltage and the source voltage of the driving transistor (DT).

The driving transistor (DT) and the scan transistor (ST) may be formed as thin film transistors. In addition, in FIG. 4, the driving transistor (DT) and the scan transistor (ST) are described mainly as being formed as P-type MOSFETs (Metal Oxide Semiconductor Field Effect Transistors), but the present invention is not limited thereto.

The driving transistor (DT) and the scan transistor (ST) may also be formed as N-type MOSFETs. In this case, the positions of the source electrodes and the drain electrodes of each of the driving transistor (DT) and the scan transistor (ST) may be changed.

In addition, in FIG. 4, the first sub-pixel (PX1), the second sub-pixel (PX2), and the third sub-pixel (PX3) each include a 2TIC 2 Transistor-1 capacitor) having one driving transistor (DT), one scan transistor (ST), and one capacitor (Cst), but the present invention is not limited thereto. The first sub-pixel (PX1), the second sub-pixel (PX2), and the third sub-pixel (PX3) each may include a plurality of scan transistors (ST) and a plurality of capacitors (Cst).

Since the second sub-pixel (PX2) and the third sub-pixel (PX3) may be expressed in substantially the same circuit diagram as the first sub-pixel (PX1), a detailed description thereof will be omitted.

The driving circuit 20 outputs signals and voltages for driving the display panel 10. To this end, the driving circuit 20 may include a data driving unit 21 and a timing control unit 22.

The data driving unit 21 receives digital video data (DATA) and a source control signal (DCS) from the timing control unit 22. The data driving unit 21 converts digital video data (DATA) into analog data voltages according to the source control signal (DCS) and supplies them to the data lines (D1 to Dm) of the display panel 10.

The timing control unit 22 receives digital video data (DATA) and timing signals from the host system. The timing signals may include a vertical sync signal, a horizontal sync signal, a data enable signal, and a dot clock. The host system may be an application processor of a smartphone or tablet PC, a monitor, a system on chip of a TV, etc.

The timing control unit 22 generates control signals for controlling the operation timing of the data driving unit 21 and the scan driving unit 30. The control signals may include a source control signal (DCS) for controlling the operation timing of the data driving unit 21 and a scan control signal (SCS) for controlling the operation timing of the scan driving unit 30.

The driving circuit 20 may be placed in a non-display area (NDA) provided on one side of the display panel 10. The driving circuit 20 may be formed as an integrated circuit (IC) and mounted on the display panel 10 using a COG (chip on glass) method, a COP (chip on plastic) method, or an ultrasonic bonding method, but the present invention is not limited thereto. For example, the driving circuit 20 may be mounted on a circuit board (not shown) rather than the display panel 10.

The data driving unit 21 may be mounted on the display panel 10 using a COG (chip on glass) method, a COP (chip on plastic) method, or an ultrasonic bonding method, and the timing control unit 22 may be mounted on a circuit board.

The scan driving unit 30 receives a scan control signal (SCS) from the timing control unit 22. The scan driving unit 30 generates scan signals according to the scan control signal (SCS) and supplies them to the scan lines (S1 to Sn) of the display panel 10. The scan driving unit 30 may include a plurality of transistors and may be formed in a non-display area (NDA) of the display panel 10. Alternatively, the scan driving unit 30 may be formed as an integrated circuit, in which case it may be mounted on a gate flexible film attached to the other side of the display panel 10.

The circuit board may be attached to pads provided at one edge of the display panel 10 using an anisotropic conductive film. As a result, lead lines of the circuit board may be electrically connected to the pads. The circuit board may be a flexible film such as a flexible printed circuit board, a printed circuit board, or a chip on film. The circuit board may be bent to the bottom of the display panel 10. As a result, one side of the circuit board may be attached to one edge of the display panel 10, and the other side may be connected to a system board disposed at the bottom of the display panel 10 and equipped with a host system.

The power supply circuit 50 may generate voltages required for driving the display panel 10 from the main power applied from the system board and supply them to the display panel 10. For example, the power supply circuit 50 may generate a high-potential voltage (VDD) and a low-potential voltage (VSS) for driving the light emitting devices (LD) of the display panel 10 from the main power and supply them to the high-potential voltage line (VDDL) and the low-potential voltage line (VSSL) of the display panel 10. In addition, the power supply circuit 50 may generate and supply driving voltages for driving the driving circuit 20 and the scan driving unit 30 from the main power.

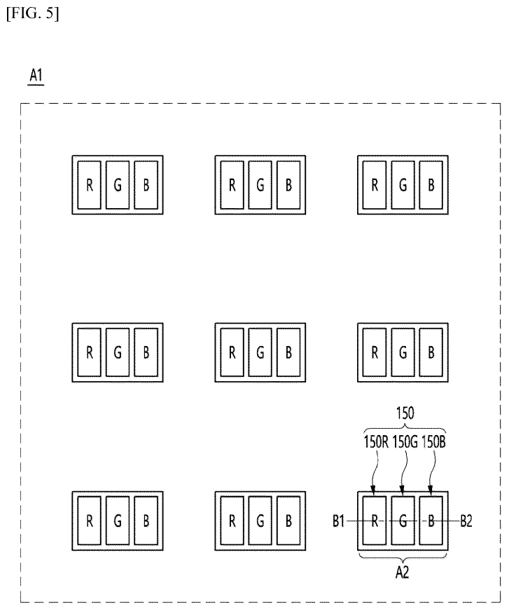

FIG. 5 is an enlarged view of the first panel area in the display device of FIG. 3.

Referring to FIG. 5, the display device 100 of the embodiment may be manufactured by mechanically and electrically connecting a plurality of panel areas such as the first panel area (A1) by tiling.

The first panel area (A1) may include a plurality of semiconductor light emitting devices 150 arranged for each unit pixel (PX) of FIG. 3.

The first panel area (A1) may include a plurality of semiconductor light emitting devices 150 arranged for each unit pixel (PX) of FIG. 3.

For example, the unit pixel (PX) may include a first sub-pixel (PX1), a second sub-pixel (PX2), and a third sub-pixel (PX3). For example, a plurality of red semiconductor light emitting devices (150R) may be arranged in the first sub-pixel (PX1), a plurality of green semiconductor light emitting devices (150G) may be arranged in the second sub-pixel (PX2), and a plurality of blue semiconductor light emitting devices (150B) may be arranged in the third sub-pixel (PX3). The unit pixel (PX) may further include a fourth sub-pixel in which no semiconductor light emitting devices are arranged, but this is not limited thereto.

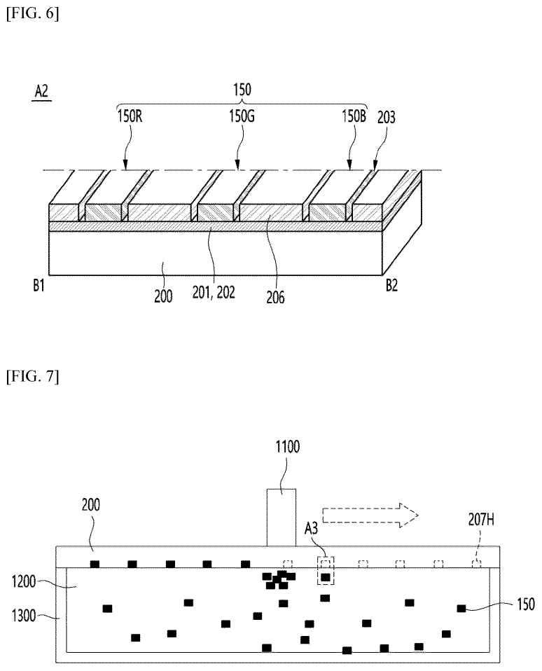

FIG. 6 is an enlarged view of the A2 area of FIG. 5. Referring to FIG. 6, the display device 100 of the embodiment may include a substrate 200, assembly wiring 201, 202, an insulating layer 206, and a plurality of semiconductor light emitting devices 150. More components may be included.

Referring to FIG. 6, the display device 100 of the embodiment may include a substrate 200, assembly wiring 201, 202, an insulating layer 206, and a plurality of semiconductor light emitting devices 150. More components may be included.

The assembly wiring may include a first assembly wiring 201 and a second assembly wiring 202 that are spaced apart from each other. The first assembly wiring 201 and the second assembly wiring 202 may be provided to generate a dielectrophoretic force (DEP force) to assemble the semiconductor light emitting device 150. For example, the semiconductor light emitting device 150 may be one of a horizontal semiconductor light emitting device, a flip-chip type semiconductor light emitting device, and a vertical semiconductor light emitting device.

The semiconductor light emitting device 150 may include a red semiconductor light emitting device 150, a green semiconductor light emitting device (150G), and a blue semiconductor light emitting device (150B) to form a unit pixel (sub-pixel), but is not limited thereto, and may also implement red and green colors by providing a red fluorescent substance and a green fluorescent substance, etc.

The substrate 200 may be a supporting member that supports components arranged on the substrate 200 or a protective member that protects the components.

The substrate 200 may be a rigid substrate or a flexible substrate. The substrate 200 may be formed of sapphire, glass, silicon, or polyimide. In addition, the substrate 200 may include a flexible material such as PEN (Polyethylene Naphthalate) or PET (Polyethylene Terephthalate). In addition, the substrate 200 may be a transparent material, but is not limited thereto. The substrate 200 may function as a support substrate in a display panel, and may also function as an assembly substrate when self-assembling a light emitting device.

The substrate 200 may be a backplane equipped with circuits, such as transistors (ST, DT), capacitors (Cst), and signal wiring, within the sub-pixels (PX1), PX2, PX3 illustrated in FIGS. 3 and 4, but is not limited thereto.

The insulating layer 206 may include an organic material having insulation and flexibility, such as polyimide, PAC, PEN, PET, polymer, etc., or an inorganic material such as silicon oxide (SiO2) or silicon nitride series (SiNx), and may be formed integrally with the substrate 200 to form a single substrate.

The insulating layer 206 may be a conductive adhesive layer having adhesiveness and conductivity, and the conductive adhesive layer may have flexibility to enable a flexible function of the display device. For example, the insulating layer 206 may be a conductive adhesive layer such as an anisotropic conductive film (ACF) or an anisotropic conductive medium, a solution containing conductive particles, etc. The conductive adhesive layer may be a layer that is electrically conductive in a direction vertical to the thickness, but electrically insulating in a direction horizontal to the thickness.

The insulating layer 206 may include an assembly hole 203 for inserting a semiconductor light emitting device 150. Therefore, during self-assembly, the semiconductor light emitting device 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light emitting device 150. For example, the red semiconductor light emitting device, the green semiconductor light emitting device, and the blue semiconductor light emitting device each have different shapes, and may have an assembly hole 203 having a shape corresponding to the shape of each of these semiconductor light emitting devices. For example, the assembly hole 203 may include a first assembly hole for assembling the red semiconductor light emitting device, a second assembly hole for assembling the green semiconductor light emitting device, and a third assembly hole for assembling the blue semiconductor light emitting device. For example, the red semiconductor light emitting device may have a circular shape, the green semiconductor light emitting device may have a first elliptical shape having a first short axis and a second long axis, and the blue semiconductor light emitting device may have a second elliptical shape having a second short axis and a second long axis, but this is not limited thereto. The second major axis of the ellipse of the blue semiconductor light emitting device may be longer than the second major axis of the ellipse of the green semiconductor light emitting device, and the second minor axis of the ellipse of the blue semiconductor light emitting device may be shorter than the first minor axis of the ellipse of the green semiconductor light emitting device.

Meanwhile, the method of mounting the semiconductor light emitting device 150 on the substrate 200 may include, for example, a self-assembly method and a transfer method.

FIG. 7 is a drawing showing an example of assembling a light emitting device according to an embodiment on a substrate by a self-assembly method.

Based on FIG. 7, an example of assembling a semiconductor light emitting device according to an embodiment on a display panel by a self-assembly method using an electromagnetic field will be described.

The assembly substrate 200 described below may also function as a panel substrate (200a) in a display device after assembling the light emitting device, but the embodiment is not limited thereto.

Referring to FIG. 7, the semiconductor light emitting device 150 may be introduced into a chamber 1300 filled with a fluid 1200, and the semiconductor light emitting device 150 may be moved to the assembly substrate 200 by a magnetic field generated from the assembly device 1100. At this time, the light emitting device 150 adjacent to the assembly hole (207H) of the assembly substrate 200 may be assembled into the assembly hole (207H) by the DEP force caused by the electric field of the assembly wirings. The fluid 1200 may be water such as ultrapure water, but is not limited thereto. The chamber may be called a water tank, a container, a vessel, etc.

After the semiconductor light emitting device 150 is introduced into the chamber 1300, the assembly substrate 200 may be placed on the chamber 1300. Depending on the embodiment, the assembly substrate 200 may also be introduced into the chamber 1300.

The semiconductor light emitting device 150 may be implemented as a vertical semiconductor light emitting device as illustrated, but is not limited thereto, and a horizontal light emitting device may be employed.

The semiconductor light emitting device 150 may include a magnetic layer (not illustrated) having a magnetic material. The magnetic layer may include a metal having magnetism, such as nickel (Ni). Since the semiconductor light emitting device 150 injected into the fluid includes a magnetic layer, it may move to the assembly substrate 200 by a magnetic field generated from the assembly device 1100. The magnetic layer may be arranged on the upper side, lower side, or both sides of the light emitting device.

The semiconductor light emitting device 150 may include a passivation layer surrounding the upper surface and the side surface. The passivation layer may be formed by using an inorganic insulator, such as silica or alumina, through PECVD, LPCVD, sputtering deposition, or the like. Additionally, the passivation layer may be formed by spin coating an organic material such as photoresist or polymer material.

The semiconductor light emitting device 150 may include a first conductivity-type semiconductor layer, a second conductivity-type semiconductor layer, and an active layer disposed therebetween. The first conductivity-type semiconductor layer may be an n-type semiconductor layer, and the second conductivity-type semiconductor layer may be a p-type semiconductor layer, but is not limited thereto. The first conductivity-type semiconductor layer, the second conductivity-type semiconductor layer, and the active layer disposed therebetween may constitute a light emitting portion. The light emitting portion may be called a light emitting layer, a light emitting region, or the like.

The first electrode (layer) may be disposed under the first conductivity-type semiconductor layer, and the second electrode (layer) may be disposed on the second conductivity-type semiconductor layer. To this end, a portion of the first conductivity-type semiconductor layer or the second conductivity-type semiconductor layer may be exposed to the outside. Accordingly, after the semiconductor light emitting device 150 is assembled on the assembly substrate 200, a portion of the passivation layer may be etched during the manufacturing process of the display device.

The first electrode may include at least one layer. For example, the first electrode may include an ohmic layer, a reflective layer, a magnetic layer, a conductive layer, an anti-oxidation layer, an adhesive layer, etc. The ohmic layer may include Au, AuBe, etc. The reflective layer may include Al, Ag, etc. The magnetic layer may include Ni, Co, etc. The conductive layer may include Cu, etc. The anti-oxidation layer may include Mo, etc. The adhesive layer may include Cr, Ti, etc.

The second electrode may include a transparent conductive layer. For example, the second electrode (154b) may include ITO, IZO, etc.

After the assembly substrate 200 is placed in the chamber, an assembly device 1100 that applies a magnetic field may move along the assembly substrate 200. The assembly device 1100 may be a permanent magnet or an electromagnet.

The assembly device 1100 may move in contact with the assembly substrate 200 to maximize the area of the magnetic field applied to the fluid 1200. Depending on the embodiment, the assembly device 1100 may include a plurality of magnetic bodies or may include magnetic bodies of a size corresponding to the assembly substrate 200. In this case, the movement distance of the assembly device 1100 may be limited to a predetermined range.

The semiconductor light emitting device 150 in the chamber 1300 may move toward the assembly device 1100 and the assembly substrate 200 by the magnetic field generated by the assembly device 1100.

The semiconductor light emitting device 150 may enter the assembly hole 207H) and be fixed by the DEP force formed by the electric field between the assembly wirings 201, 202 while moving toward the assembly device 1100.

Specifically, the first and second assembly wirings 201, 202 form an electric field by an AC power source, and a DEP force may be formed between the assembly wirings 201, 202 by this electric field. The semiconductor light emitting device 150 may be fixed to the assembly hole 207H) on the assembly board 200 by this DEP force.

At this time, a predetermined solder layer (not shown) is formed between the light emitting device 150 assembled on the assembly hole 207H) of the assembly board 200 and the assembly wiring 201, 202, thereby improving the bonding strength of the light emitting device 150.

In addition, a molding layer (not shown) may be formed in the assembly hole 207H) of the assembly board 200 after assembly. The molding layer may be a transparent resin or a resin containing a reflective material or a scattering material.

Since the time required for each semiconductor light emitting device to be assembled on a substrate may be drastically shortened by the self-assembly method using the electromagnetic field described above, a large-area, high-pixel display may be implemented more quickly and economically.

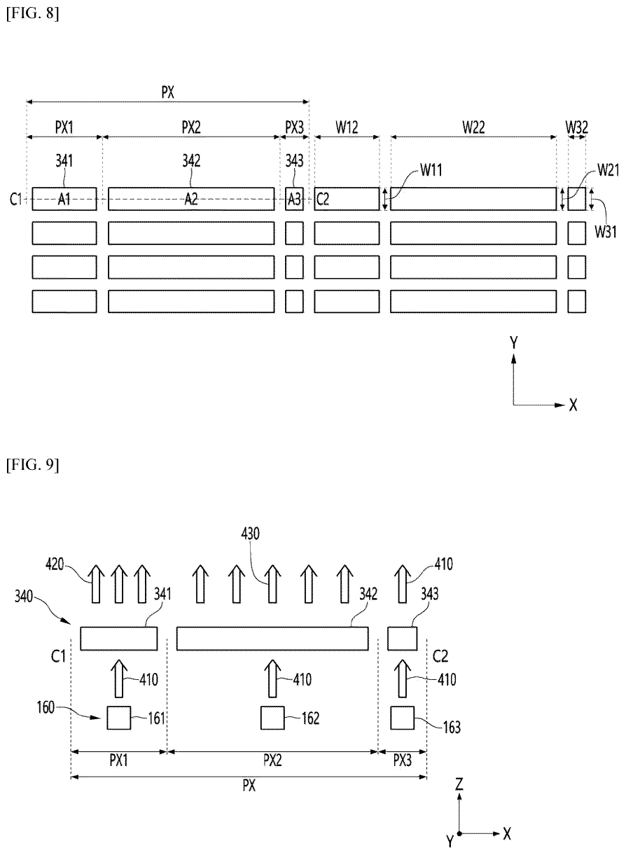

FIG. 8 is a schematic plan view of a display device according to an embodiment. FIG. 9 is a schematic cross-sectional view of a display device according to an embodiment.

Referring to FIGS. 8 and 9, the display device according to the embodiment may include a light source 160 and a color converter 340.

The light source 160 may generate light and provide it to the color converter 340. For example, the light generated from the light source 160 may be blue light 410, but is not limited thereto. For example, the light generated from the light source 160 may be light of a lower wavelength band than the wavelength band of the blue light 410, for example, blue light or purple light, but is not limited thereto. The color converter 340 may convert the blue light 410 to output light of a different color. For example, the light of a different color may be red light 420 and green light 430.

Meanwhile, a plurality of pixels may be arranged. The plurality of pixels may be arranged in a matrix. For example, the plurality of pixels may be arranged along a first direction (x), and the plurality of pixels may be arranged along a second direction (y).

Each of the plurality of pixels may be capable of implementing a plurality of colors. Each of the plurality of pixels may include a plurality of sub-pixels. Each of the plurality of sub-pixels may emit light of different colors. An image may be displayed by light of different colors emitted from each of the plurality of sub-pixels.

For example, each of the plurality of sub-pixels may include a first sub-pixel (PX1), a second sub-pixel (PX2), and a third sub-pixel (PX3).

For example, the first sub-pixel (PX1) may emit red light 420, the second sub-pixel (PX2) may emit green light 430, and the third sub-pixel (PX3) may emit blue light 410.

Meanwhile, the light source 160 may include a plurality of semiconductor light emitting devices 161, 162, 163. Each of the plurality of semiconductor light emitting devices 161, 162, 163 may emit blue light 410.

The first sub-pixel (PX1) may include at least one semiconductor light emitting device 161. The second sub-pixel (PX2) may include at least one semiconductor light emitting device 162. The third sub-pixel (PX3) may include at least one semiconductor light emitting device 163.

The color converter 340 may include a first color conversion pattern 341, a second color conversion pattern 342, and a light transmitting pattern 343. The light transmitting pattern 343 may be omitted.

Each of the first color conversion pattern 341 and the second color conversion pattern 342 may include color conversion particles. For example, the first color conversion pattern 341 may include red conversion particles, and the second color conversion pattern 342 may include green conversion particles. The color conversion particles may include, for example, a fluorescent substance or a quantum dot. Each of the fluorescent substance or the quantum dot may include fluorescent particles or quantum particles.

As another example, each of the first color conversion pattern 341, the second color conversion pattern 342, and/or the light transmitting pattern 343 may include a scattering agent capable of scattering light. The scattering agent may include scattering particles.

The first color conversion pattern 341 may be arranged in the first sub-pixel (PX1) to convert blue light 410 of the semiconductor light emitting device 161 to output red light 420. For example, the first color conversion pattern 341 may shift light in the blue wavelength band of the semiconductor light emitting device 161 to light in the red wavelength band, and output light in the shifted red wavelength band. The second color conversion pattern 342 may be arranged in the second sub-pixel (PX2) to output green light 430 from blue light 410 of the semiconductor light emitting device 162. For example, the second color conversion pattern 342 may shift light in the blue wavelength band of the semiconductor light emitting device 162 to light in the green wavelength band, and output light in the shifted green wavelength band. The light emitting pattern 343 is arranged in the third sub-pixel (PX3) to allow blue light 410 of the semiconductor light emitting device 163 to pass through. For example, the third sub-pixel (PX3) may allow light of the blue wavelength band of the semiconductor light emitting device 163 to pass through and output light of the blue wavelength band as is.

Blue light 410 may be named as first color light, red light 420 may be named as second color light, and green light 430 may be named as third color light.

Accordingly, the first sub-pixel (PX1) may include at least one semiconductor light emitting device 161 and a first color conversion pattern 341, the second sub-pixel (PX2) may include at least one semiconductor light emitting device 162 and a second color conversion pattern 342, and the third sub-pixel (PX3) may include at least one semiconductor light emitting device 163 and a light transmitting pattern 343.

The first color conversion pattern 341 may have a shape or area corresponding to the first sub-pixel (PX1), the second color conversion pattern 342 may have a shape or area corresponding to the second sub-pixel (PX2), and the light transmitting pattern 343 may have a shape or area corresponding to the third sub-pixel (PX3).

As described above, in the past, when the area of the color conversion layer 3 in FIG. 1 arranged in each sub-pixel was the same, the blue light 410 was not only greater than the red light 420 or the green light 430 in terms of light emission intensity, but also the color conversion efficiency was different from each other due to the material characteristics of the color conversion layer 3 arranged in each sub-pixel, so that color temperature adjustment was required.

Therefore, as shown in Table 1, gamma correction was performed for color temperature adjustment. Before gamma correction, the luminance of red, green, and blue were each 173.16 cd/m2. In this case, the luminance in white was high at 201 cd/m2.

However, when gamma correction was performed, the luminance of red could be 68.89201 cd/m2, the luminance of green could be 173.16 cd/m2, and the luminance of blue could be 99 cd/m2. In this case, the luminance in white was 99201 cd/m2, which was significantly lower than the luminance in white before gamma adjustment.

TABLE 1

| | | Luminance | Area |
|---|---|---|---|
| | Color | (cd/m² | Ratio (%) |
| Before | Red | 173.16 | 100 |
| adjustment | Green | 173.16 | 100 |
| White | Blue | 173.16 | 100 |
| Balance | White | 201 | |
| After adjustment | Red | 68.89 | 100 |
| (Gamma | Green | 173.16 | 100 |
| Adjustment) White | Blue | 18.42 | 100 |
| Balance | White | 99 | |
| ( | | | |

As shown in Table 1, when performing gamma correction to overcome the color temperature difference, the brightness in white is significantly reduced, which is a technical issue that needs to be resolved urgently as it may lead to a deterioration in image quality.

According to the embodiment, the above-described technical issue may be resolved by making the areas (A1, A2, A3) of the first color conversion pattern 341, the second color conversion pattern 342, and the light transmitting pattern 343 different.

Specifically, the area (A2) of the second color conversion pattern 342 may be larger than the area (A1) of the first color conversion pattern 341, and the area (A1) of the first color conversion pattern 341 may be larger than the area (A3) of the light transmitting pattern 343.

For example, the area (A1) of the first color conversion pattern 341 may be 26±5% of the total area, the area (A2) of the second color conversion pattern 342 may be 67±5% of the total area, and the area (A3) of the light transmitting pattern 343 may be 7±5% of the total area. Here, the total area may be the sum A1+A2+A3 of the area of the first color conversion pattern 341, the area of the second color conversion pattern 342, and the area of the light transmitting pattern 343.

As described above, by making the area (A3) of the light transmitting pattern 343 where blue light 410 is output the smallest, and making the area (A2) of the second color conversion pattern 342 with the worst color conversion efficiency the largest, the brightness may be significantly improved, as shown in Table 2.

TABLE 2

| Color | Luminance (cd/m² | Area Ratio (%) |
|---|---|---|
| Red | 138 | 26.4 |
| Green | 345 | 66.5 |
| Blue | 37 | 7.1 |
| White | 520 | |

As shown in Table 2, since the area ratio of the second color conversion pattern 342 is the largest at 66.5%, the brightness is also the largest at 345 cd/m2. By making the area ratio of the light transmitting pattern 343 through which the blue light 410 with the highest brightness intensity is transmitted 7.1%, the brightness is weak at 37 cd/m2. In this way, by varying the area (A1) of the first color conversion pattern 341, the area (A2) of the second color conversion pattern 342, and the area (A3) of the light transmitting pattern 343, the brightness is increased by more than 5 times compared to the brightness in white after the conventional gamma adjustment.

Therefore, by varying the area (A1) of the first color conversion pattern 341, the area (A2) of the second color conversion pattern 342, and the area (A3) of the light transmitting pattern 343, not only may the calculation circuit be simplified by eliminating the need for gamma adjustment as before, but brightness may also be significantly improved, thereby enhancing reliability through high image quality.

Meanwhile, the first widths (W11, W21, W31) of each of the first color conversion pattern 341, the second color conversion pattern 342, and the light transmitting pattern 343 along the second direction (y) may be the same, and the second widths (W12, W22, W32) of each of the first color conversion pattern 341, the second color conversion pattern 342, and the light transmitting pattern 343 along the first direction(x) may be different. For example, the second width (W22) of the second color conversion pattern 342 may be larger than the second width (W12) of the first color conversion pattern 341, and the second width (W12) of the first color conversion pattern 341 may be larger than the second width (W32) of the light transmitting pattern 343.

For example, when the first widths (W11, W21, W31) of each of the first color conversion pattern 341, the second color conversion pattern 342, and the light transmitting pattern 343 along the second direction (y) are the same, the second width (W12) of the first color conversion pattern 341 may be 26±5% of the total width, the second width (W22) of the second color conversion pattern 342 may be 67-5% of the total width, and the second width (W32 of the light transmitting pattern 343 may be 7=5% of the total width. Here, the total width may be the sum (W12+W22+W32) of the second width of the first color conversion pattern 341, the second width of the second color conversion pattern 342, and the second width of the light transmitting pattern 343.

Although not shown, the first widths (W11, W21, W31) of each of the first color conversion pattern 341, the second color conversion pattern 342, and the light transmitting pattern 343 along the second direction (y) may be different, and the second widths (W12, W22, W32) of each of the first color conversion pattern 341, the second color conversion pattern 342, and the light transmitting pattern 343 along the first direction (x) may be the same.

Although not shown, the first widths (W11, W21, W31) of each of the first color conversion pattern 341, the second color conversion pattern 342, and the light transmitting pattern 343 along the second direction (y) may be different, and the second widths (W12, W22, W32) of each of the first color conversion pattern 341, the second color conversion pattern 342, and the light transmitting pattern 343 along the first direction (x) may be different.

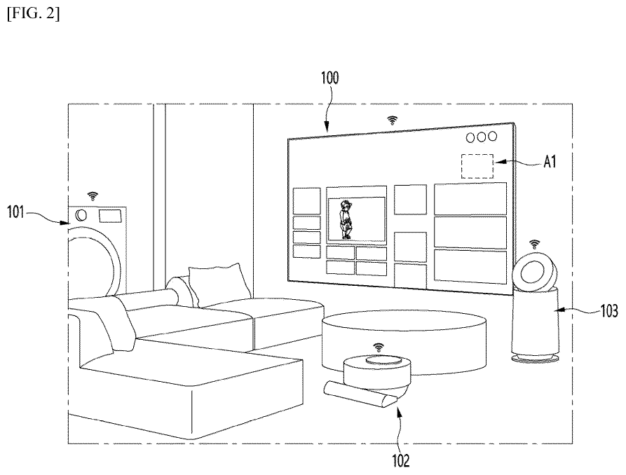

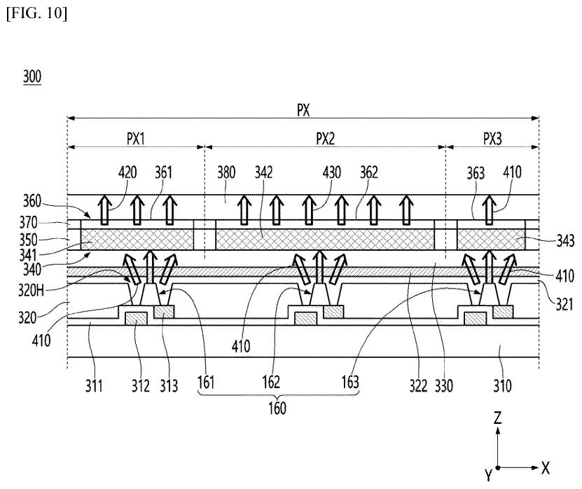

The detailed structure of the display device (FIGS. 1 and 2 described above) will be described in detail with reference to FIGS. 10 to 13c below. Any description omitted in the following description may be easily understood from the display device (FIGS. 1 and 2 described above).

### FIRST EMBODIMENT

FIG. 10 is a cross-sectional view illustrating a display device according to the first embodiment.

The display device according to the first embodiment is an in-cell display device, in which a light source 160 and a color converter 340 may be manufactured on the same substrate.

Referring to FIG. 10, the display device 300 according to the first embodiment may include a first substrate 310, a plurality of insulating layers 311, 321, 330, first and second assembly wirings 312, 313, a barrier wall 320, a light source 160, an electrode wiring 322, a color converter 340, a bank 350, a color filter layer 360, a light-shielding pattern 370, and a second substrate 380.

The light source 160 may include a plurality of semiconductor light sources and elements 161, 162, 163. The color converter 340 may include a first color conversion pattern 341, a second color conversion pattern 342, and a light transmitting pattern 343. Since the light source 160 and the color converter 340 have been described above, a detailed description thereof will be omitted.

Since the semiconductor light emitting devices 161, 162, 163 have a size of less than a micrometer, it is very difficult to mount them on the first substrate 310.

In the embodiment, the semiconductor light emitting devices 161, 162, 163 may be easily assembled on the first substrate 310 using a self-assembly method.

As a structure for the self-assembly method, a first substrate 310, a plurality of insulating layers 311, 321, 330, first and second assembly wirings 312, 313, and a barrier wall 320 may be provided, and since these components have been described above, a detailed description thereof will be omitted.

Although the drawing shows that the first and second assembly wirings 312, 313 are arranged on different layers, the first and second assembly wirings 312, 313 may be arranged on the same layer. As shown in FIG. 10, the first assembly wiring 312 may be arranged under the insulating layer 311, and the second assembly wiring 313 may be arranged on the insulating layer 311. Although not shown, the first and second assembly wirings 312, 313 may be arranged between the first substrate 310 and the insulating layer 311.

By performing a self-assembly process, semiconductor light emitting devices 161, 162, 163 in a fluid are moved in one direction by a magnetic field, and the semiconductor light emitting devices 161, 162, 163 may be inserted and fixed into the assembly hole 320H) of the barrier wall 320 by the DEP force formed between the first and second assembly wirings 312, 313. For example, the assembly hole 320H) of the barrier wall 320 is different in the first sub-pixel (PX1), the second sub-pixel (PX2), and the third sub-pixel (PX3), and the semiconductor light emitting devices 161, 162, 163 of each of the first sub-pixel (PX1), the second sub-pixel (PX2), and the third sub-pixel (PX3) may have a shape corresponding to the shape of the different assembly hole 320H). With this structure, semiconductor light emitting devices 161, 162, 163 corresponding to the assembly holes 320H) of each of the first sub-pixel (PX1), the second sub-pixel (PX2), and the third sub-pixel (PX3) may be assembled simultaneously using a self-assembly method. Alternatively, semiconductor light emitting devices 161, 162, 163 of each of the first sub-pixel (PX1), the second sub-pixel (PX2), and the third sub-pixel (PX3) may be individually assembled into the first sub-pixel (PX1), the second sub-pixel (PX2), and the third sub-pixel (PX3), but this is not limited thereto.

For convenience, since the drawing shows one assembly hole 320H) provided in each of the first sub-pixel (PX1), the second sub-pixel (PX2), and the third sub-pixel (PX3), one semiconductor light emitting device 161, 162, 163 is arranged in each of the first sub-pixel (PX1), the second sub-pixel (PX2), and the third sub-pixel (PX3), but two or more assembly holes 320H) may be provided in each of the first sub-pixel (PX1), the second sub-pixel (PX2), and the third sub-pixel (PX3), so that two or more semiconductor light emitting devices 161, 162, 163 may be arranged in each of the first sub-pixel (PX1), the second sub-pixel (PX2), and the third sub-pixel (PX3). The number of semiconductor light emitting devices 161, 162, 163 arranged in each of the first sub-pixel (PX1), the second sub-pixel (PX2), and the third sub-pixel (PX3) may vary depending on the size of each of the first sub-pixel (PX1), the second sub-pixel (PX2), and the third sub-pixel (PX3), the size of the semiconductor light emitting devices 161, 162, 163, the maximum brightness value required for each of the first sub-pixel (PX1), the second sub-pixel (PX2), and the third sub-pixel (PX3), etc.

After the semiconductor light emitting device 161, 162, 163 is assembled, the electrode wiring 322 may be arranged on the semiconductor light emitting device 161, 162, 163 and electrically connected to one side of the semiconductor light emitting device 161, 162, 163. In addition, since the second assembly wiring 313 is electrically connected to the other side of the semiconductor light emitting device 161, 162, 163, the second assembly wiring 313 may be used as an electrode wiring. For example, the second assembly wiring 313 may be named a first electrode wiring, and the electrode wiring 322 may be named a second electrode wiring. Blue light 410 may be emitted from the semiconductor light emitting device 161, 162, 163 by power applied to the second assembly wiring 313 and the electrode wiring 322.

Meanwhile, the electrode wiring 322 may be commonly connected to the semiconductor light emitting devices 161, 162, 163 of each of the first sub-pixel (PX1), the second sub-pixel (PX2), and the third sub-pixel (PX3). In this case, the brightness of the semiconductor light emitting devices 161, 162, 163 may vary depending on the intensity of the power applied to the second assembly wiring 313.

When blue light 410 having the same brightness is emitted from each of the first sub-pixel (PX1), the second sub-pixel (PX2), and the third sub-pixel (PX3), the intensity of the power applied to the second assembly wiring 313 arranged in each of the first sub-pixel (PX1), the second sub-pixel (PX2), and the third sub-pixel (PX3) is the same. Accordingly, after the semiconductor light emitting devices 161, 162, 163 are arranged in each of the first sub-pixel (PX1), the second sub-pixel (PX2), and the third sub-pixel (PX3) through the self-assembly process, the second assembly wiring 313 arranged in each of the first sub-pixel (PX1), the second sub-pixel (PX2), and the third sub-pixel (PX3) may be commonly connected, but this is not limited thereto.

Although not shown, after the semiconductor light emitting devices 161, 162, 163 are placed in each of the first sub-pixel (PX1), the second sub-pixel (PX2), and the third sub-pixel (PX3) by the self-assembly process, the first assembly wiring 312 may also be electrically connected to the other side of the semiconductor light emitting devices 161, 162, 163 through an electrical connection process.

A color converter 340 may be placed on the light source 160, that is, on the plurality of semiconductor light emitting devices 161, 162, and 163. Specifically, the first color conversion pattern 341 may be placed in the first sub-pixel (PX1), the second color conversion pattern 342 may be placed in the second sub-pixel (PX2), and the transparent pattern may be placed in the third sub-pixel (PX3).

A bank 350 may be arranged between each of the first color conversion pattern 341, the second color conversion pattern 342, and the transparent pattern. The bank 350 may be a guide member for forming the first color conversion pattern 341, the second color conversion pattern 342, and the transparent pattern. The bank 350 may be a color mixing prevention member for preventing color mixing between the red light 420 output from the first color conversion pattern 341, the green light 430 output from the second color conversion pattern 342, and the blue light 410 transmitted through the light transmitting pattern 343.

The plurality of insulating layers 311, 321, 330 may include an organic material or an inorganic material.

For example, the first insulating layer 311 may be disposed between the first assembly wiring 312 and the second assembly wiring 313 to electrically insulate the first assembly wiring 312 and the second assembly wiring 313 and contribute to the formation of DEP force during the self-assembly process. For example, the second insulating layer 321 may be disposed on the semiconductor light emitting devices 161, 162, 163 to be a protective member that may protect the semiconductor light emitting devices 161, 162, 163 from external impact, foreign substances, moisture, etc. In addition, the second insulating layer 321 may be a planarizing layer to facilitate the formation of the electrode wiring 322. To this end, the second insulating layer 321 may be disposed on the barrier wall 320 as well as the semiconductor light emitting devices 161, 162, 163, and may have an upper surface that is parallel to the ground. The electrode wiring 322 is made of metal and is formed on the second insulating layer 321 through a deposition process. If a bend is formed on the upper surface of the second insulating layer 321, an electrical short circuit may occur. Therefore, by forming the upper surface of the second insulating layer 321 parallel to the ground, the metal is formed on the second insulating layer 321 without an electrical short circuit, and the electrode wiring 322 may be electrically connected to one side of the semiconductor light emitting device 161, 162, 163 through a subsequent pattern process.

The third insulating layer 330 may be placed between the electrode wiring 322 and the color converter 340. If the third insulating layer 3330 is omitted and the color converter 340 comes into contact with the electrode wiring 322, power is applied to the electrode wiring 322 for the light emission of the semiconductor light emitting devices 161, 162, 163, so that heat is generated in the electrode wiring 322, and this heat affects the material properties of the color converter 340, so that the color conversion efficiency of each of the color converter 340, i.e., the first color conversion pattern 341 and the second color conversion pattern 342 may be reduced. Accordingly, this problem may be solved by placing the third insulating layer 330 between the electrode wiring 322 and the color converter 340.

Meanwhile, a color converter 340 may be placed on the third insulating layer 330. The color converter 340 may include a first color conversion pattern 341, a second color conversion pattern 342, and a light transmitting pattern 343.

According to an embodiment, the area (A1) of the first color conversion pattern 341, the area (A2) of the second color conversion pattern 342, and the area (A3) of the light transmitting pattern 343 may be different. For example, the area (A2) of the second color conversion pattern 342 may be larger than the area (A1) of the first color conversion pattern 341, and the area (A1) of the first color conversion pattern 341 may be larger than the area (A3) of the light transmitting pattern 343. With this structure, the brightness in white may be significantly increased, thereby improving the image quality.

A color filter layer 360 may be placed on the color converter 340. The color filter layer 360 may include a first color filter 361, a second color filter 362, and a third color filter 363.

The first color filter 361 may output the target red light among the red light 420 output from the first color conversion pattern 341 by passing it through. The second color filter 362 may output the target green light among the green light 430 output from the second color conversion pattern 342 by passing it through. The third color filter 363 may output the target blue light among the blue light 410 output from the light transmitting pattern 343 by passing it through. Accordingly, the pass wavelength band of the first color filter 361 may set within the wavelength band of the red light 420 output from the first color conversion pattern 341, the pass wavelength band of the second color filter 362 may set within the wavelength band of the green light 430 output from the second color conversion pattern 342, and the pass wavelength band of the third color filter 363 may be set within the wavelength band of the blue light 410 output from the light transmitting pattern 343, but is not limited thereto.

If the wavelength band of the red light 420 output from the first color conversion pattern 341 is the same as the wavelength band of the target red light, the first color filter 361 may be omitted. If the wavelength band of the green light 430 output from the second color conversion pattern 342 is the same as the wavelength band of the target green light, the second color filter 362 may be omitted. If the wavelength band of the blue light 410 output from the light transmitting pattern 343 is the same as the wavelength band of the target blue light, the third color filter 363 may be omitted.

For example, the first color filter 361 may be arranged on the first color conversion pattern 341, the second color filter 362 may be arranged on the second color conversion pattern 342, and the third color filter 363 may be arranged on the light transmitting pattern 343. For example, the first color filter 361 may be arranged to correspond to the first color conversion pattern 341, the second color filter 362 may be arranged to correspond to the second color conversion pattern 342, and the third color filter 363 may be arranged to correspond to the light transmitting pattern 343. In this case, the area of the first color filter 361 may be the same as the area (A1) of the first color conversion pattern 341, the area of the second color filter 362 may be the same as the area (A2) of the second color conversion pattern 342, and the area of the third color filter 363 may be the same as the area (A3) of the light transmitting pattern 343, but is not limited thereto.

For example, the area (A2) of the second color filter 362 may be larger than the area (A1) of the first color filter 361, and the area (A1) of the first color filter 361 may be larger than the area (A3) of the third color filter 363.

Meanwhile, the first color filter 361 and the second color filter 362 may be set to transmit light of the same wavelength band. For example, the first color filter 361 and the second color filter 362 may be set to transmit light of a yellow wavelength band. In this case, the third color filter 363 may be omitted. In this case, red light 420 of a lower wavelength band is output by the first color filter 361, green light 430 of a higher wavelength band is output by the second color filter 362, and blue light 410 is directly output from the light projection pattern 343 of the converter 340, so that the color temperature may be lowered and the color purity may be improved.

Meanwhile, the light-shielding pattern 370 may be placed between each of the first color filter 361, the second color filter 362, and the third color filter 363. The light-shielding pattern 370 may prevent interference or color mixing between the red light 420 output from the first color filter 361, the green light 430 output from the second color filter 362, and the blue light 410 output from the third color filter 363. The light-shielding pattern 370 may be called a black matrix.

Meanwhile, the second substrate 380 may play a role in protecting the color converter 340 and the color filter layer 360. The second substrate 380 may include a rigid material such as glass or a soft material such as epoxy.

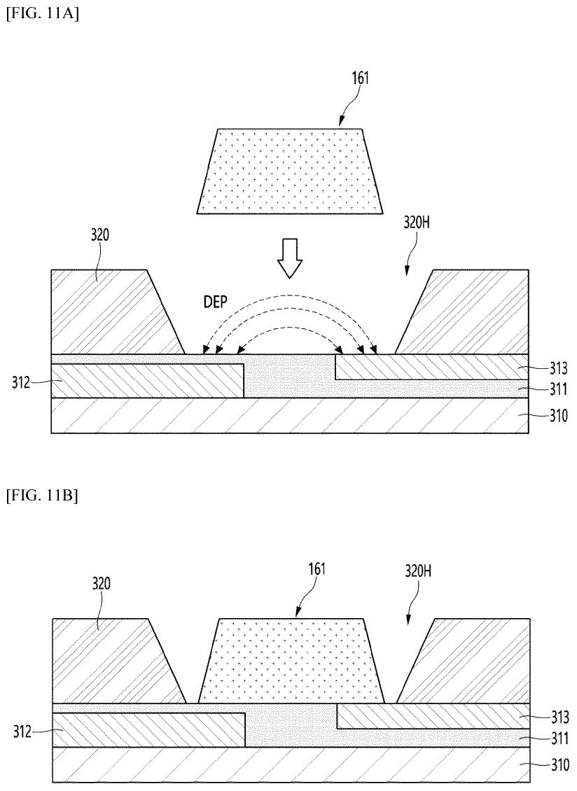

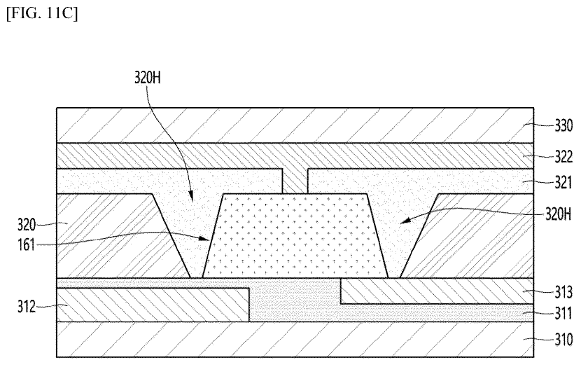

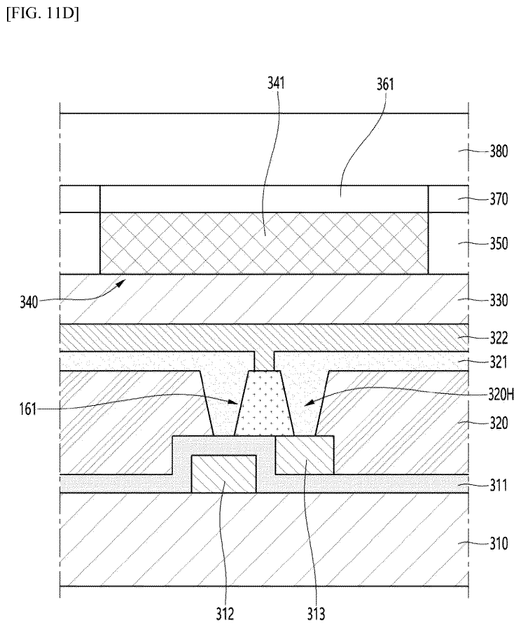

FIGS. 11A to 11D are drawings explaining a manufacturing process of a display device according to the first embodiment. FIGS. 11A to 11D illustrate a process for manufacturing a display device corresponding to a first sub-pixel, but display devices corresponding to each of the second sub-pixel and the third sub-pixel may also be manufactured using the same process as the process for manufacturing a display device corresponding to the first sub-pixel illustrated in FIGS. 11A to 11D.

As illustrated in FIGS. 11A and 11B, a semiconductor light emitting device 161 may be assembled on a first substrate 310 using a self-assembly process. For example, the semiconductor light emitting device 161 may be assembled into a first sub-pixel of the first substrate 310. For example, the semiconductor light emitting device 161 may be assembled into an assembly hole 320H) formed in a barrier wall 320 corresponding to a first sub-pixel of the first substrate 310.

As described above, when the semiconductor light emitting devices 161 move in the fluid by the magnetic field, one of the semiconductor light emitting devices 161 may be pulled by the DEP force formed between the first and second assembly wirings 312, 313 provided in the first sub-pixel, and assembled into the corresponding assembly hole 320H).

As illustrated in FIG. 11c, after an insulating layer 321 is formed on the semiconductor light emitting device 161 and the barrier wall 320, the insulating layer 321 may be partially etched to form a contact hole exposing the upper side of the semiconductor light emitting device 161.

Afterwards, an electrode wiring 322 may be formed by forming and etching a metal film on the insulating layer 321. The electrode wiring 322 may be electrically connected to the upper side of the semiconductor light emitting device 161. Meanwhile, the second assembly wiring 313 is exposed to the assembly hole 320H), and the semiconductor light emitting device 161 is assembled into the assembly hole 320H), so that the second assembly wiring 313 may be electrically connected to the lower side of the semiconductor light emitting device 161. At this time, the second assembly wiring 313 may also be used as the electrode wiring. Therefore, the semiconductor light emitting device 161 may emit light by power applied to the electrode wiring 322 and the second assembly wiring 313.

As described above, blue light 410 may be emitted from semiconductor light emitting devices 161, 162, 163 of FIG. 10 arranged in each of the plurality of first sub-pixels, the plurality of second sub-pixels, and the plurality of third sub-pixels defined on the first substrate 310.

After that, an insulating layer 330 may be formed on the electrode wiring 322.

As illustrated in FIG. 11d, a bank 350 and a color converter 340 may be formed on the insulating layer 330.

First, a bank 350 may be formed along the periphery of the first sub-pixel. In this case, a groove may be formed in the central region of the first sub-pixel by the cutting layer 330 and the bank 350.

Afterwards, a first color conversion pattern 341 of the color converter 340 may be formed in the corresponding groove. As described above, color conversion particles may be included in the first color conversion pattern 341. For example, the color conversion particles may include red conversion particles capable of converting blue light 410 of the semiconductor light emitting device 161 into red light 420. Although not shown, a second color conversion pattern 342 of the color converter 340 may be formed in the groove of the second sub-pixel, and a light transmitting pattern 343 of the color converter 340 may be formed in the groove of the third sub-pixel. The second color conversion pattern 342 may include green conversion particles capable of converting blue light 410 of the semiconductor light emitting device 162 of FIG. 10 into green light 430. The light transmitting pattern 343 may not include color conversion particles. Accordingly, blue light 410 of the semiconductor light emitting device 163 in FIG. 10 may be transmitted through the light transmitting pattern 343 and output forward.

Meanwhile, in the embodiment, the area (A1) of the first color conversion pattern, the area (A2) of the second color conversion pattern 342, and the area (A3) of the light transmitting pattern 343 may be different. Accordingly, the areas of each of the first sub-pixel, the second sub-pixel, and the third sub-pixel may also be different.

For example, the area of the second sub-pixel may be larger than the area of the first sub-pixel, and the area of the first sub-pixel may be larger than the area of the third sub-pixel. Since the bank 350 is formed along the periphery of each of the first sub-pixel, the second sub-pixel, and the third sub-pixel, and the areas of each of the first sub-pixel, the second sub-pixel, and the third sub-pixel are different, the grooves formed by the bank 350 in each of the first sub-pixel, the second sub-pixel, and the third sub-pixel may be different. Accordingly, the areas (A1, A2, A3) of the first color conversion pattern 341, the second color conversion pattern 342, and the light transmitting pattern 343 formed in the grooves of each of the first sub-pixel, the second sub-pixel, and the third sub-pixel may also be different. For example, the area (A2) of the second color conversion pattern 342 may be larger than the area (A1) of the first color conversion pattern 341, and the area (A1) of the first color conversion pattern 341 may be larger than the area (A3) of the light transmitting pattern 343.

As described above, by making the areas (A1, A2, A3) of the first color conversion pattern 341, the second color conversion pattern 342, and the light transmitting pattern 343 different, the operation circuit may be simplified because there is no need for gamma adjustment as in the past, and the brightness may be significantly improved, thereby enhancing reliability through high image quality.

After that, a light-shielding pattern 370 may be formed on the bank 350, and a color filter layer 360 may be formed on the color converter 340. The color filter layer 360 may include a first color filter 361, a second color filter 362, and a third color filter 363. In this case, the first color filter 361 may be formed on the first color conversion pattern 341, the second color filter 362 may be formed on the second color conversion pattern 342, and the third color filter 363 may be formed on the light transmitting pattern 343.

In the drawing, the width (or area) of the shading pattern 370 is depicted as being the same as the width (or area) of the bank 350, but the width (or area) of the shading pattern 370 may be larger or smaller than the width (or area) of the bank 350.

In the drawing, the width (or area) of the first color filter 361 is depicted as being the same as the width (or area) of the first color conversion pattern 341, the width (or area) of the second color filter 362 is depicted as being the same as the width (or area) of the second color conversion pattern 342, and the width (or area) of the third color filter 363 is depicted as being the same as the width (or area) of the light transmitting pattern 343, but they may be different.

Meanwhile, a second substrate 380 may be formed on the shading pattern 370 and the color filter layer 360.

### SECOND EMBODIMENT

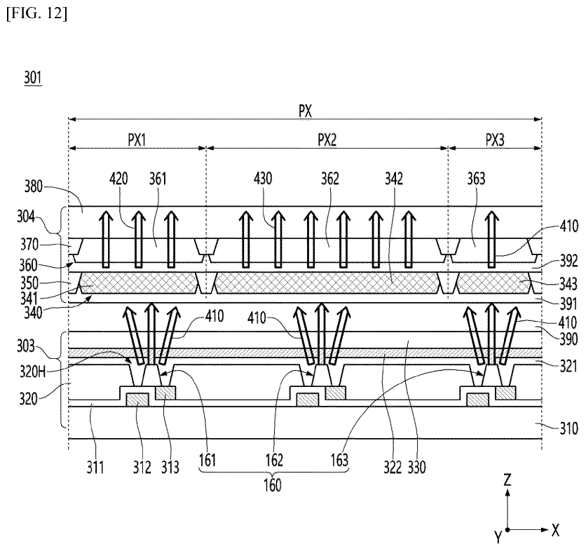

FIG. 12 is a cross-sectional view illustrating a display device according to the second embodiment.

The display device according to the first embodiment is a remote-type display device, and after a light source 160 and a color converter 340 are manufactured on each of different first substrates 310, the light source 160 and the color converter 340 may be joined to face each other.

In the second embodiment, drawing symbols having the same shape, structure, and/or function as those in the first embodiment are given the same drawing symbols and a detailed description is omitted.

Referring to FIG. 12, the display device 301 according to the second embodiment may include a lower substrate 303, an adhesive member 390, and an upper substrate 304.

The lower substrate 303 may include a first substrate 310, an insulating layer 311, 321, 330, first and second assembly wiring 311, 312, a barrier wall 320, a light source 160, and an electrode wiring 322, since these components have been described in detail in the first embodiment, a detailed description thereof will be omitted.

The upper substrate 304 may include a second substrate 380, a light-shielding pattern 370, a color filter layer 360, a bank 350, a color converter 340, and an insulating layer 391, 392.

The adhesive member 390 may serve to bond the lower substrate 303 and the upper substrate 304. The adhesive member 390 may be called an adhesive layer, an adhesive material, an adhesive, an insulating layer, an insulating member, etc.

The display device 301 may be manufactured by bonding the lower substrate 303 and the upper substrate 304 using the adhesive material 390.

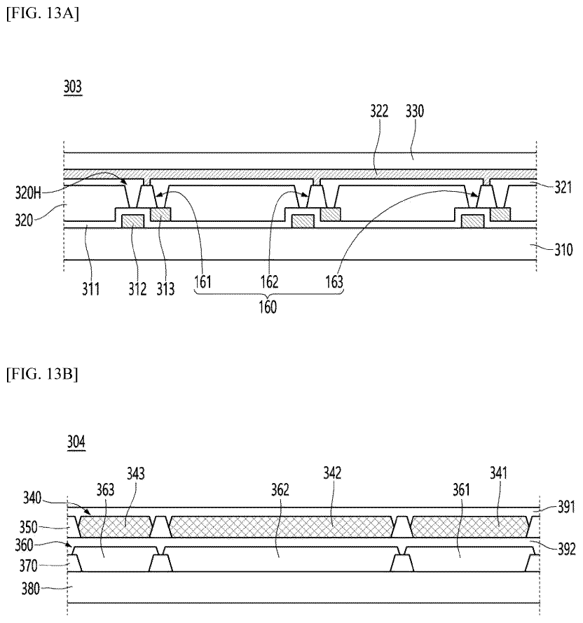

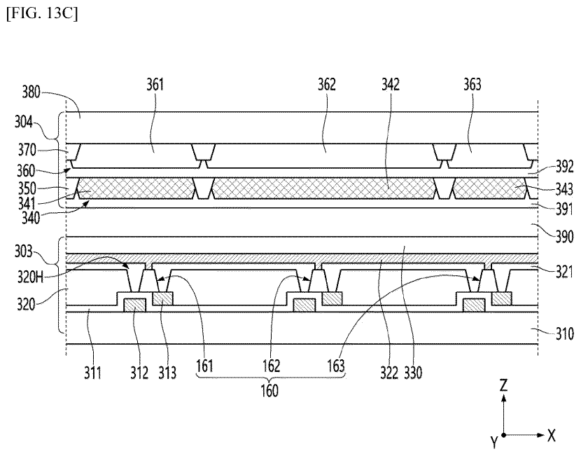

The manufacturing process of the display device according to the second embodiment will be described in more detail with reference to FIGS. 13A to 13C.

As shown in FIG. 13A, after the barrier wall 320 having the first and second assembly wirings 312, 313 and the assembly hole 320H) is formed on the first substrate 310, a self-assembly process is performed so that the semiconductor light emitting devices 161, 162, 163 may be assembled into the assembly hole 320H). Thereafter, the electrode wiring 322, etc. are formed, so that the lower substrate 303 may be manufactured through a post-process.

As illustrated in FIG. 13b, a light-shielding pattern 370 and a color filter layer 360 are formed on a second substrate 380, a bank 350 is formed on the light-shielding pattern 370, and a color converter 340 is formed on the color filter layer 360, whereby the upper substrate 304 may be manufactured. An insulating layer 292 may be formed between the light-shielding pattern 370 and the bank 350 and between the color filter layer 360 and the color converter 340. An insulating layer 291 may be formed on the bank 350 and the color converter 340.

As shown in FIG. 13c, an adhesive member 390 may be formed on the insulating layer 330 of the lower substrate 303 and/or the insulating layer 291 of the upper substrate 304.

After that, by flipping the lower substrate 303 or the upper substrate 304 by 180°, and then cooling the lower substrate 303 or the upper substrate 304 after thermal bonding, a remote display device may be manufactured.

Meanwhile, the display device according to the first embodiment 300 of FIG. 10 and the display device according to the second embodiment 301 of FIG. 12 may be a display panel. That is, in the embodiment, the display device and the display panel may be understood to have the same meaning. In the embodiment, the display device in a practical sense may include a display panel and a controller (or processor) that may control the display panel to display an image.

The above detailed description should not be construed as restrictive in all respects but should be considered as illustrative. The scope of the embodiments should be determined by a reasonable interpretation of the appended claims, and all changes within the equivalent scope of the embodiments are included in the scope of the embodiments.

### INDUSTRIAL APPLICABILITY

The embodiment may be adopted in the field of displays that display images or information. The embodiments may be adopted in the field of displays that display images or information using semiconductor light emitting devices. The semiconductor light emitting devices may be micro-level semiconductor light emitting devices or nano-level semiconductor light emitting devices.

For example, the embodiments may be adopted in TVs, signage, smart phones, mobile phones, mobile terminals, HUDs for automobiles, backlight units for laptops, and display devices for VR or AR.

1. A display device comprising:
a substrate comprising a first sub-pixel, a second sub-pixel, and a third sub-pixel;
at least one semiconductor light emitting device for each of the first sub-pixel, the second sub-pixel, and the third sub-pixel;
a first color conversion pattern disposed on the at least one semiconductor device corresponding to the first sub-pixel and comprising first color conversion particles;
a second color conversion pattern disposed on the at least one semiconductor device corresponding to the second sub-pixel and comprising second color conversion particles; and
a light transmitting pattern disposed on the at least one semiconductor device corresponding to the third sub-pixel,
wherein an area of the first color conversion pattern, an area of the second color conversion pattern, and an area of the light transmitting pattern are different, and
wherein an area of a light emitting area of the first sub-pixel, an area of a light emitting area of the second sub-pixel, and an area of a light emitting area of the third sub-pixel are the same.

2. The display device according to claim 1, wherein the semiconductor light emitting devices of each of the first sub-pixel, the second sub-pixel and the third sub-pixel are configured to generate light of the same color.

3. The display device according to claim 1, wherein the semiconductor light emitting device is configured to generate a first color light,
wherein the first color conversion pattern is configured to convert the first color light into a second color light,
wherein the second color conversion pattern is configured to convert the first color light into a third color light, and
wherein the light transmitting pattern is configured to transmit the first color light.

4. The display device according to claim 3, wherein the first color light comprises blue light, the second color light comprises red light, and the third color light comprises green light.

5. The display device according to claim 1, wherein the area of the second color conversion pattern is larger than the area of the first color conversion pattern.

6. The display device according to claim 5, wherein the area of the first color conversion pattern is larger than the area of the light transmitting pattern.

7. The display device according to claim 1, wherein the area of the first color conversion pattern is 26±5% of a total area, the area of the second color conversion pattern is 67±5% of the total area, and the area of the light transmitting pattern is 7±5% of the total area, and
wherein the total area is the sum of the area of the first color conversion pattern, the area of the second color conversion pattern, and the area of the light transmitting pattern.

8. The display device according to claim 1, wherein first widths of each of the first color conversion pattern, the second color conversion pattern, and the light transmitting pattern along a first direction are the same, and
wherein second widths of each of the first color conversion pattern, the second color conversion pattern, and the light transmitting pattern along a second direction are different.

9. The display device according to claim 8, wherein the second width of the second color conversion pattern is greater than the second width of the first color conversion pattern.

10. The display device according to claim 9, wherein the second width of the first color conversion pattern is larger than the second width of the light transmitting pattern.

11. The display device according to claim 1, further comprising a bank between each of the first color conversion pattern, the second color conversion pattern and the light transmitting pattern.

12. The display device according to claim 1, further comprising a first color filter on the first color conversion pattern; a second color filter on the second color conversion pattern; a third color filter on the light transmitting pattern; and a light-shielding pattern between each of the first color filter, the second color filter, and the third color filter.

13. The display device according to claim 11, wherein the area of the second color filter is larger than the area of the first color filter, and the area of the first color filter is larger than an area of the third color filter.

14. The display device according to claim 13, wherein a pass wavelength band of the first color filter is set within a wavelength band range of red light, a pass wavelength band of the second color filter is set within a wavelength band range of green light, and a pass wavelength band of the third color filter is set within a wavelength band range of blue light.

15. The display device according to claim 13, wherein the first color filter and the second color filter are set to transmit light in an yellow wavelength band.

16. The display device according to claim 1, further comprising a first assembly wiring and a second assembly wiring are provided for each of the first sub-pixel, the second sub-pixel and the third sub-pixel; and a barrier wall is provided on the first assembly wiring and second assembly wiring and has at least one assembly hole for each of the first sub-pixel, the second sub-pixel and the third sub-pixel.

17. The display device according to claim 16, wherein each of the at least one semiconductor light emitting device is positioned in the at least one assembly hole.

18. The display device according to claim 17, further comprising an insulating layer on the barrier wall and the at least one semiconductor light emitting device; and an electrode wiring disposed on the insulating layer and connected to one side of the at least one semiconductor light emitting device, and
wherein at least one of the first and second assembly wirings is connected to an other side of the at least one semiconductor light emitting device.

19. The display device according to claim 16, wherein the first and second assembly wirings of the first sub-pixel vertically overlap with the first color conversion pattern,
wherein the first and second assembly wirings of the second sub-pixel vertically overlap with the second color conversion pattern, and
wherein the first and second assembly wirings of the third sub-pixel vertically overlap with the light-emitting pattern.

20. The display device according to claim 1, wherein a thickness of the first color conversion pattern, a thickness of the second color conversion pattern, and a thickness of the light-transmitting pattern are the same.
